(19) United States
(12) Patent Application Publication
(10) Pub. No.: US 2007/0048937 A1
(43) Pub. Date: Mar. 1, 2007

(54) METHOD OF FABRICATING NON-VOLATILE MEMORY

(76) Inventors: Chin-Chung Wang, Hsinchu (TW); Chia-Ping Lai, Kaohsiung (TW); Che-Huai Hung, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,165

(22) Filed: Dec. 19, 2005

(30) Foreign Application Priority Data
Aug. 29, 2005 (TW) 94129440

(51) Int. Cl. H01L 21/336

(52) U.S. Cl. 438/257

(57) ABSTRACT

A method of fabricating a non-volatile memory is provided. A substrate having a memory cell area and a peripheral circuit area is provided. A plurality of device isolation structures is formed in the substrate. A tunneling dielectric layer is formed on the substrate in the memory cell area and a gate oxide layer is formed on the substrate in the peripheral circuit area. A first conductive layer is formed on the substrate to cover the memory cell area and the peripheral circuit area. The first conductive layer in the memory cell area is patterned. A composite dielectric layer is formed on the substrate. The composite dielectric layer in the peripheral circuit area is removed. A second conductive layer is formed on the substrate to cover the memory cell area and the peripheral circuit area.

### CROSS-REFERENCE TO RELATED APPLICATION

This application claims the priority benefit of Taiwan application serial no. 94129440, filed on Aug. 29, 2005. All disclosure of the Taiwan application is incorporated herein by reference.

### BACKGROUND OF THE INVENTION

1. Field of the Invention

The present invention relates to a method of fabricating a semiconductor device, more particularly, to a method of fabricating a non-volatile memory.

2. Description of the Related Art

Memory is a semiconductor device designed to store data and parameters. As the function and capacity of the microprocessor in a computer increase and become increasingly powerful, programs and computing of the software applications in the computer expand significantly. Hence, the need for memory increases correspondingly. Fabricate memories of higher capacity and lower cost to meet the continuously growing demand has become the driving force for developing the techniques and processes for fabricating memory device in the semiconductor industry toward a higher level of integration.

Among the many kinds of memory products, non-volatile memory is a type of memory that allows multiple data writing, reading and erasing operations. The stored data will be retained even after power to the device is removed. With these advantages, non-volatile memory has become one of the most widely adopted memory devices for personal computer and electronic equipment.

FIGS. 1A through 1C are schematic cross-sectional views showing the steps for fabricating a non-volatile memory. First, as shown in FIG. 1A, a substrate 100 is provided. The substrate 100 has a memory cell area 102 and a peripheral circuit area 104. Furthermore, the substrate 100 has a plurality of device isolation structures 106 formed thereon for defining an active region. Then, a tunneling dielectric layer 108 is formed on the substrate. Thereafter, a conductive layer 110 is formed on the substrate 100 to cover the device isolation structure 106.

As shown in FIG. 1B, a patterned photoresist layer (not shown) is formed over the substrate 100 in the memory cell area 102. The conductive layer 110 is patterned to form a plurality of linear conductive strips 110a. In the meantime, the conductive layer 110 in the peripheral circuit area 104 is removed to expose the tunneling dielectric layer 108. After that, an inter-gate dielectric layer 112 is formed over the substrate 100.

Thereafter, as shown in FIG. 1C, a photoresist layer (not shown) is formed over the memory cell area 102. Then, a wet etching operation is carried out to remove the inter-gate dielectric layer 112 and the tunneling dielectric layer 108 in the peripheral circuit area 104 and expose the substrate 100. Next, a gate oxide layer 114 is formed over the peripheral circuit area 104. Finally, a conductive layer 116 is formed over the substrate 100.

However, the device isolation structures 106 are fabricated using silicon oxide and the inter-gate dielectric layer 112 and the tunneling dielectric layer 108 are fabricated using an identical material. Hence, the etching solution used for removing the inter-gate dielectric layer 112 and the tunneling dielectric layer 108 in the peripheral circuit area 104 in the wet etching operation will also erode the device isolation structures 106 underneath the substrate 100. Consequently, divots are formed at the corner regions 118. Therefore, after forming the gate oxide layer 114, the gate oxide layer 114 at the corner regions 118 has a smaller thickness and will easily produce a leakage current and result in a short circuit. Ultimately, the reliability and yield of the device will drop significantly.

### SUMMARY OF THE INVENTION

Accordingly, at least one objective of the present invention is to provide a method of fabricating a non-volatile memory capable of resolving the problem of having a thinner gate oxide layer at corner regions and increasing both the reliability and yield of the device.

To achieve these and other advantages and in accordance with the purpose of the invention, as embodied and broadly described herein, the invention provides a method of fabricating a non-volatile memory. First, a substrate is provided. The substrate has a memory cell area and a peripheral circuit area. Then, a plurality of device isolation structures is formed in the substrate. Thereafter, a tunneling dielectric layer is formed on the substrate in the memory cell area and then a gate oxide layer is formed on the substrate in the peripheral circuit area. A first conductive layer is formed on the substrate to cover the memory cell area and the peripheral circuit area. The first conductive layer in the memory cell area is patterned. Then, a composite dielectric layer is formed on the substrate. The composite dielectric layer in the peripheral circuit area is removed. After that, a second conductive layer is formed on the substrate to cover the memory cell area and the peripheral circuit area.

According to the method of fabricating a non-volatile memory in the embodiment of the present invention, after forming the second conductive layer over the substrate, may further include patterning the second conductive layer, the composite dielectric layer and the first conductive layer in the memory cell area and patterning the second conductive layer in the peripheral circuit area.

According to the method of fabricating a non-volatile memory in the embodiment of the present invention, the device isolation structures are shallow trench isolation (STI) structures, for example.

According to the method of fabricating a non-volatile memory in the embodiment of the present invention, the tunneling dielectric layer is fabricated using silicon oxide, for example.

According to the method of fabricating a non-volatile memory in the embodiment of the present invention, the tunneling dielectric layer has an actual thickness of about 90 Å, for example.

According to the method of fabricating a non-volatile memory in the embodiment of the present invention, the process of forming the tunneling dielectric layer includes performing a thermal oxidation, for example.

According to the method of fabricating a non-volatile memory in the embodiment of the present invention, the gate oxide layer is fabricated using silicon oxide, for example.

According to the method of fabricating a non-volatile memory in the embodiment of the present invention, the gate oxide layer has an actual thickness of about 150 Å, for example.

According to the method of fabricating a non-volatile memory in the embodiment of the present invention, the process of forming the gate oxide layer includes performing a wet oxidation, for example.

According to the method of fabricating a non-volatile memory in the embodiment of the present invention, the process of forming the gate oxide layer includes forming a mask layer over the memory cell area, performing a dopant implant, removing the mask layer and performing a thermal oxidation process.

According to the method of fabricating a non-volatile memory in the embodiment of the present invention, the first conductive layer is fabricated using doped polysilicon, for example.

According to the method of fabricating a non-volatile memory in the embodiment of the present invention, the second conductive layer is also fabricated using doped polysilicon, for example.

According to the method of fabricating a non-volatile memory in the embodiment of the present invention, the inter-gate dielectric layer is an oxide/nitride/oxide composite layer, for example.

According to the method of fabricating a non-volatile memory in the embodiment of the present invention, the process of removing the composite dielectric layer in the peripheral circuit area includes performing a wet etching operation, a dry etching operation and another wet etching operation in sequence, for example.

The present invention also provides an alternative method of fabricating a non-volatile memory. First, a substrate is provided. The substrate has at leas a memory cell area and a peripheral circuit area. Then, a plurality of device isolation structures is formed in the memory cell area and the peripheral circuit area of the substrate. Thereafter, a tunneling dielectric layer is formed on the substrate in the memory cell area and then a gate oxide layer is formed on the substrate in the peripheral circuit area. A first conductive layer is formed on the substrate in the memory cell area to cover the tunneling dielectric layer and on the substrate in the peripheral circuit area to cover the gate oxide layer. Then, a patterned mask layer is formed over the substrate to cover the first conductive layer in the peripheral circuit area and a portion of the first conductive layer in the memory cell area. Then, an inter-gate dielectric layer is formed on the substrate to cover the first conductive layer in the memory cell area and the peripheral circuit area. After that, a first mask layer is formed to cover the memory cell area. The inter-gate dielectric layer in the peripheral circuit area is removed. Finally, a second conductive layer is formed over the substrate on the inter-gate dielectric layer of the memory cell area and on the first conductive layer of the peripheral circuit area.

According to the method of fabricating a non-volatile memory in the embodiment of the present invention, the process of forming a tunneling oxide layer in the memory cell area and a gate oxide layer in the peripheral circuit area includes forming a second mask layer over the memory cell area. Then, a dopant implant is performed. Thereafter, the second mask layer is removed and a thermal oxidation process is performed.

According to the method of fabricating a non-volatile memory in the embodiment of the present invention, the device isolation structures are shallow trench isolation (STI) structures, for example.

According to the method of fabricating a non-volatile memory in the embodiment of the present invention, the tunneling dielectric layer is fabricated using silicon oxide, for example.

According to the method of fabricating a non-volatile memory in the embodiment of the present invention, the tunneling dielectric layer has an actual thickness of about 90 Å, for example.

According to the method of fabricating a non-volatile memory in the embodiment of the present invention, the process of forming the tunneling dielectric layer includes performing a thermal oxidation, for example.

According to the method of fabricating a non-volatile memory in the embodiment of the present invention, the gate oxide layer is fabricated using silicon oxide, for example.

According to the method of fabricating a non-volatile memory in the embodiment of the present invention, the gate oxide layer has an actual thickness of about 150 Å, for example.

According to the method of fabricating a non-volatile memory in the embodiment of the present invention, the process of forming the gate oxide layer includes performing a wet oxidation, for example.

According to the method of fabricating a non-volatile memory in the embodiment of the present invention, after forming the second conductive layer, further includes patterning the second conductive layer, the inter-gate dielectric layer and the first conductive layer in the memory cell area.

According to the method of fabricating a non-volatile memory in the embodiment of the present invention, the first conductive layer is fabricated using doped polysilicon, for example.

According to the method of fabricating a non-volatile memory in the embodiment of the present invention, the second conductive layer is also fabricated using doped polysilicon, for example.

According to the method of fabricating a non-volatile memory in the embodiment of the present invention, the inter-gate dielectric layer is an oxide/nitride/oxide composite layer, for example.

In the present invention, a gate oxide layer is directly formed over the substrate in the peripheral circuit area after forming the device isolation structures. Then, a first conductive layer is simultaneously formed over the peripheral circuit area and the memory cell area. Thereafter, a photoresist layer is used to protect the first conductive layer in the peripheral circuit area while patterning the first conductive layer in the memory cell area. After that, an inter-gate dielectric layer is simultaneously formed over the memory cell area and the peripheral circuit area. Then, the photoresist layer is used to protect the inter-gate dielectric layer in the memory cell area while removing the inter-gate dielectric layer in the peripheral circuit area. Afterwards, a second conductive layer is formed over the substrate. Hence, in the etching process for removing the inter-gate dielectric layer in the peripheral circuit area, the first conductive layer can be used as an etching stop layer. This etching stop layer prevents the etching solution from eroding the device isolation structures underneath the surface of the substrate to produce a particularly thin gate oxide layer at the corner regions in the peripheral circuit area.

Furthermore, the processes for fabricating the memory cell area and the peripheral circuit area are carried out simultaneously. Thus, the film layers formed on the memory cell area and the peripheral circuit areas have almost the same thickness. Therefore, the subsequent planarization can produce a better planarizing effect.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1C are schematic cross-sectional views showing the steps for fabricating a non-volatile memory.

FIGS. 2A through 2C are schematic cross-sectional views showing the steps for fabricating a non-volatile memory according to one embodiment of the present invention.

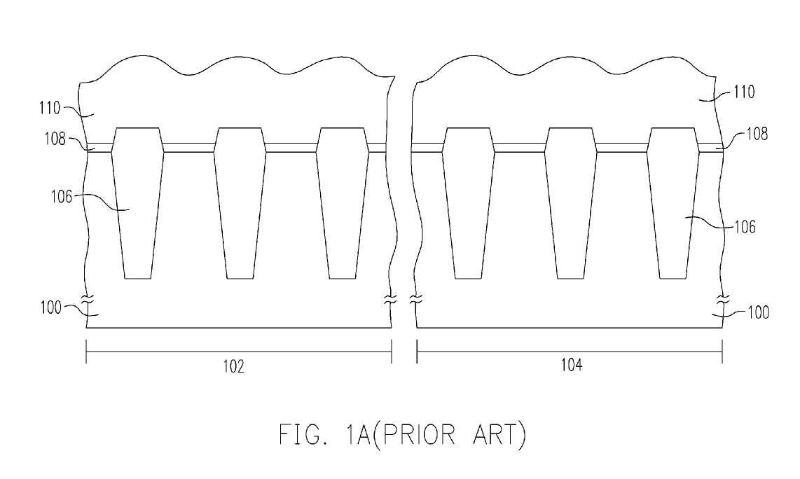

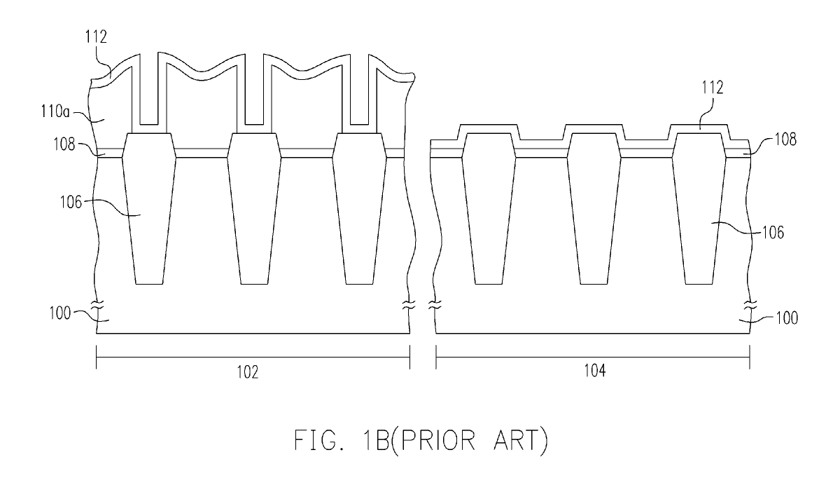

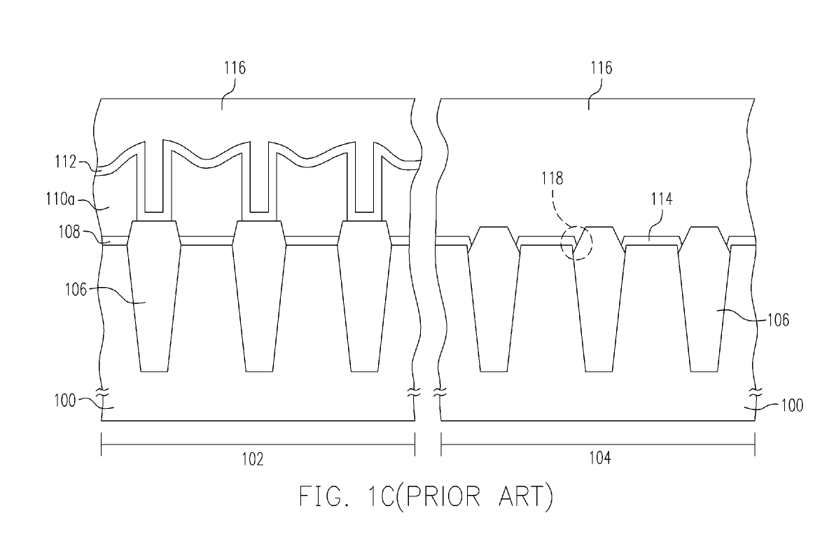

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

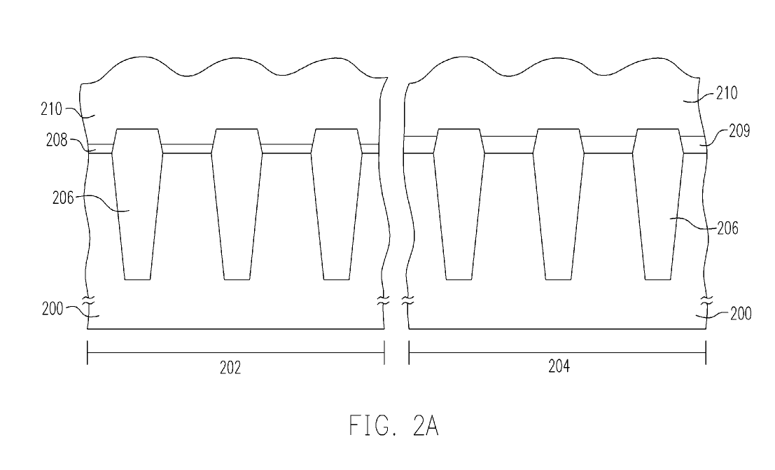

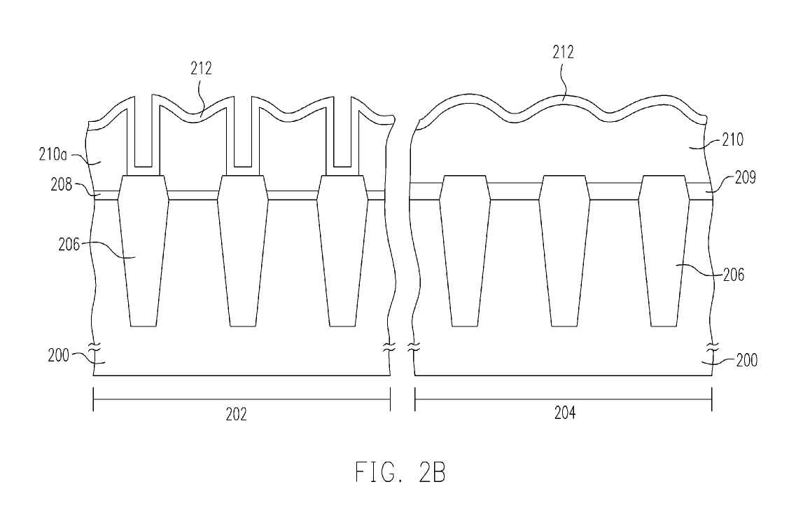

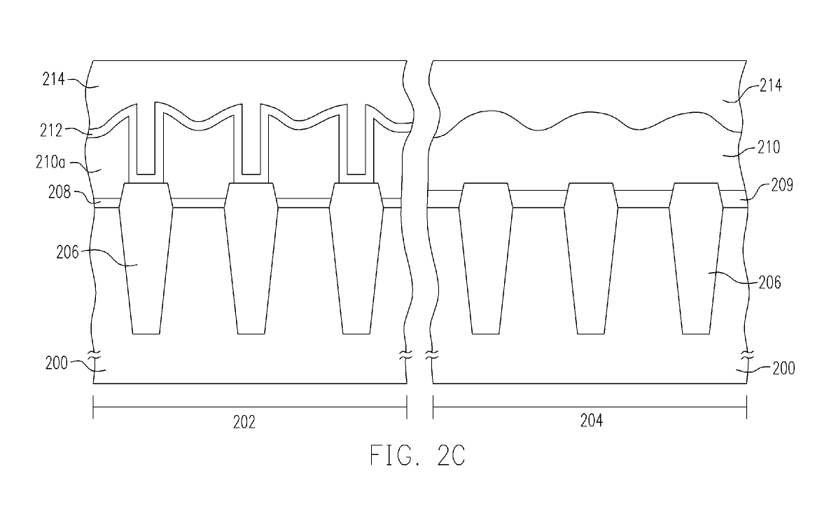

FIGS. 2A through 2C are schematic cross-sectional views showing the steps for fabricating a non-volatile memory according to one embodiment of the present invention. First, as shown in FIG. 2A, a substrate 200 having a memory cell area 202 and a peripheral circuit area 204 is provided. Then, a plurality of device isolation structures 206 is formed in the substrate 200. The device isolation structures 206 are formed, for example, by performing a local oxidation of silicon (LOCOS) or a shallow trench isolation (STI) process. Thereafter, a tunneling dielectric layer 208 is formed on the substrate in the memory cell area 202 and a gate oxide layer 209 is formed on the substrate in the peripheral circuit area 204. The tunneling dielectric layer 208 is fabricated using silicon oxide, for example. The tunneling dielectric layer 208 has a thickness of about 90 Å and is formed, for example, by performing a thermal oxidation. On the other hand, the gate oxide layer 209 is fabricated using silicon oxide, for example. The gate oxide layer 209 has a thickness of about 150 Å and is formed, for example, by performing a wet oxidation operation. Thereafter, a conductive layer 210 is formed over the substrate 200. The conductive layer 210 is fabricated using doped polysilicon and formed, for example, by depositing an undoped polysilicon layer in a chemical vapor deposition process and performing an ion implant process thereafter.

In another embodiment, the method of forming the gate oxide layer 209 may include forming a mask layer (not shown) over the memory cell area 202 to expose the peripheral circuit area 204. Then, a dopant implantation is carried out to implant dopants into the peripheral circuit area 204. After removing the mask layer, a thermal oxidation process is performed to form the tunneling dielectric layer 208 and the gate oxide layer 209 each having a different thickness.

As shown in FIG. 2B, a patterned mask layer (not shown) is formed over the substrate 200 to cover the entire peripheral circuit area 204. Then, the conductive layer 210 in the memory cell area 202 is patterned to form a plurality of conductive strips 210a serving as floating gates. Thereafter, a composite dielectric layer 212 is formed over the conductive layers 210, 210a to serves as a gate dielectric layer. The composite dielectric layer 212 is an oxide/nitride/oxide composite layer, for example. The method of forming the composite dielectric layer 212 includes performing a thermal oxidation to produce a first silicon oxide layer and performing a chemical vapor deposition process to form a silicon nitride layer and another silicon oxide layer in sequence over the first silicon oxide layer, for example.

As shown in FIG. 2C, another mask layer (not shown) is formed over the memory cell area 202 for removing the composite dielectric layer 212 in the peripheral circuit area 204 and exposing the conductive layer 210. The method of removing the composite dielectric layer 212 in the peripheral circuit area 204 includes the following steps. First, a wet etching operation is performed to remove the upper silicon oxide layer. Then, a dry etching operation is performed to remove the silicon nitride layer. Finally, a wet etching operation is performed again to remove the lower silicon oxide layer. In the process of removing the composite dielectric layer 212, the conductive layer 210 is used as an etching stop layer preventing the device isolation structures 206 and the gate oxide layer 208 underneath the conductive layer 210 from being damaged by the corrosive etching solution.

Thereafter, a conductive layer 214 is formed over the substrate 200. The conductive layer 214 serves as a control gate and is fabricated using doped polysilicon, for example. The conductive layer 214 is formed, for example, by performing a chemical vapor deposition process to form an undoped polysilicon layer and performing an ion implant process thereafter. After that, the conductive layer 214, the composite dielectric layer 212 and the conductive layer 210a in the memory cell area are patterned to form stacked gate structures. In the meantime, the conductive layer 214 in the peripheral circuit area is also patterned to form gate structures in the peripheral circuit area 204. Then, other familiar processes for completing the fabrication of the non-volatile memory are performed. Since these processes should be familiar and have already been described elsewhere, a detailed description is omitted here.

In summary, a gate oxide layer 208 is directly formed over the substrate 200 in the peripheral circuit area 204 after forming the device isolation structures 206. Then, a conductive layer 210 is simultaneously formed over the peripheral circuit area 204 and the memory cell area 202. Thereafter, using a photoresist layer as a protective layer to protect the conductive layer 210 in the peripheral circuit area 204, the conductive layer 210 in the memory cell area 202 is patterned. After that, an inter-gate dielectric layer 212 is simultaneously formed over the memory cell area 202 and the peripheral circuit area 204. Then, using the photoresist layer as a protective layer to protect the inter-gate dielectric layer 212 in the memory cell area 202, the inter-gate dielectric layer 212 in the peripheral circuit area 204 is removed. Afterwards, another conductive layer 214 is formed over the substrate 200. Hence, in a subsequent etching process for removing the inter-gate dielectric layer 212 in the peripheral circuit area 204, the conductive layer 210 over the gate oxide layer 209 can be used as an etching stop layer. This etching stop layer prevents the etching solution from eroding the gate oxide layer 209 and the device isolation structures 206 lying underneath the surface of the substrate 200 to produce divots at the corner regions resulting in a particularly thin gate oxide layer at the corner regions. Ultimately, a drop in performance resulting from a leakage current in the device is prevented.

Furthermore, the processes for fabricating the memory cell area and the peripheral circuit area are carried out simultaneously. Therefore, the film layers formed on the memory cell area and the peripheral circuit areas have almost the same thickness. As a result, the subsequent planarization can produce a better planarizing effect. In addition, the etching time of a subsequent etching process can be more readily controlled to prevent film layers from over-etched.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a non-volatile memory, comprising:
providing a substrate, wherein the substrate has a memory cell area and a peripheral circuit area;
forming a plurality of device isolation structures in the substrate;
forming a tunneling dielectric layer on the substrate in the memory cell area and forming a gate oxide layer on the substrate in the peripheral circuit area;
forming a first conductive layer on the substrate to cover the memory cell area and the peripheral circuit area;
patterning the first conductive layer in the memory cell area;
forming a composite dielectric layer over the substrate;
removing the composite dielectric layer in the peripheral circuit area; and
forming a second conductive layer on the substrate to cover the memory cell area and the peripheral circuit area.

2. The method of claim 1, after forming the second conductive layer over the substrate, further comprising patterning the second conductive layer, the composite dielectric layer and the first conductive layer in the memory cell area, and patterning the second conductive layer in the peripheral circuit area.

3. The method of claim 1, wherein the device isolation structure comprising a shallow trench isolation (STI) structure.

4. The method of claim 1, wherein the material constituting the tunneling dielectric layer comprising silicon oxide.

5. The method of claim 1, wherein the tunneling dielectric layer has an actual thickness of about 90 Å.

6. The method of claim 1, wherein the step of forming the tunneling dielectric layer comprising performing a thermal oxidation.

7. The method of claim 1, wherein the material constituting the gate oxide layer comprising silicon oxide.

8. The method of claim 1, wherein the gate oxide layer has an actual thickness of about 150 Å.

9. The method of claim 1, wherein the step of forming the gate oxide layer comprising performing a wet oxidation operation.

10. The method of claim 1, wherein the step of forming the gate oxide layer comprising:
forming a mask layer over the memory cell area;
performing a dopant implant process;
removing the mask layer; and
performing a thermal oxidation.

11. The method of claim 1, wherein the material constituting the first conductive layer comprising doped polysilicon.

12. The method of claim 1, wherein the composite dielectric layer comprising an oxide/nitride/oxide composite layer.

13. The method of claim 12, wherein the step for removing the composite dielectric layer in the peripheral circuit area comprising performing a wet etching operation, a dry etching operation and another wet etching operation in sequence.

14. A method of fabricating a non-volatile memory, comprising:
providing a substrate, wherein the substrate has at least a memory cell area and a peripheral circuit area;
forming a plurality of device isolation structures in the memory cell area and the peripheral circuit area of the substrate;
forming a tunneling dielectric layer on the substrate in the memory cell area and forming a gate oxide layer on the substrate in the peripheral circuit area;
forming a first conductive layer over the substrate to cover the tunneling dielectric layer in the memory cell area and the gate oxide layer in the peripheral circuit area;
forming a patterned mask layer over the substrate to cover the first conductive layer in the peripheral circuit area and a portion of the first conductive layer in the memory cell area;
patterning the first conductive layer in the memory cell area by using the patterned mask layer as a mask;
forming an inter-gate dielectric layer over the substrate to cover the first conductive layer in the memory cell area and the peripheral circuit area;
forming a first mask layer to cover the memory cell area;
removing the inter-gate dielectric layer in the peripheral circuit area; and
forming a second conductive layer over the inter-gate dielectric layer in the memory cell area and the first conductive layer in the peripheral circuit area of the substrate.

15. The method of claim 14, wherein the step for forming the tunneling oxide layer in the memory cell area and the gate oxide layer in the peripheral circuit area further comprising:
forming a second mask layer over the memory cell area;
performing a dopant implant;
removing the second mask layer; and
performing a thermal oxidation.

16. The method of claim 14, wherein the device isolation structure comprising a shallow trench isolation (STI) structure.

17. The method of claim 14, wherein the material constituting the tunneling dielectric layer comprising silicon oxide.

18. The method of claim 14, wherein the tunneling dielectric layer has an actual thickness of about 90 Å.

19. The method of claim 14, wherein the step of forming the tunneling dielectric layer comprising performing a thermal oxidation.

20. The method of claim 14, wherein the material constituting the gate oxide layer comprising silicon oxide.

21. The method of claim 14, wherein the gate oxide layer has an actual thickness of about 150 Å.

22. The method of claim 14, wherein the step of forming the gate oxide layer comprising performing a wet etching operation.

23. The method of claim 14, after forming the second conductive layer, further comprising patterning the second conductive layer, the inter-gate dielectric layer and the first conductive layer in the memory cell area.

24. The method of claim 14, wherein the material constituting the first conductive layer comprising doped polysilicon.

25. The method of claim 14, wherein the material constituting the second conductive layer comprising doped polysilicon.

26. The method of claim 14, wherein the inter-gate dielectric layer comprising an oxide/nitride/oxide composite layer.
